(19) United States
(12) Patent Application Publication
(10) Pub. No.: US 2009/0110532 A1
(43) Pub. Date: Apr. 30, 2009

(54) METHOD AND APPARATUS FOR PROVIDING WAFER CENTERING ON A TRACK LITHOGRAPHY TOOL

(75) Inventor: Mohsen S. Salek, Saratoga, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SOKUDO CO., LTD., Kyoto (JP)

(21) Appl. No.: 11/927,008

(22) Filed: Oct. 29, 2007

(51) Int. Cl. H01L 21/68; B25J 15/00; B65G 29/00; G05B 19/18; H01L 21/02

(52) U.S. Cl. 414/757; 414/816; 438/758; 700/62; 74/490.03; 901/11; 901/16

(57) ABSTRACT

An apparatus for centering a substrate in a track lithography tool includes a processing chamber having an opening large enough to admit the substrate. The processing chamber includes a substrate support member. The substrate is characterized by a diameter and comprises a mounting surface, a process surface, and an edge. The apparatus also includes a clamped robot blade including a substrate support surface adapted to support the mounting surface of the substrate, two edge contact regions, and a base contact region. The clamped robot blade also includes a clamping system adapted to move at least one of the two edge contact regions or the base contact region from an unclamped position to a clamped position, thereby making contact between the edge of the substrate and the two edge contact regions and the base contact region in the clamped position. The apparatus further includes a robot arm coupled to the clamped robot blade.

### BACKGROUND OF THE INVENTION

The present invention relates generally to the field of substrate processing equipment. More particularly, the present invention relates to a method and apparatus for performing wafer centering on a track lithography tool. Merely by way of example, the method and apparatus of the present invention utilize an wafer position correction system with a clamped robot blade to prevent misalignment of a substrate upon the robot blade. The method and system can be applied to other semiconductor processing chambers commonly used in semiconductor processing equipment.

Modern integrated circuits contain millions of individual elements that are formed by patterning the materials that make up the integrated circuit, such as silicon, metal and/or dielectric layers, to sizes that are small fractions of a micrometer. One of the techniques used throughout the industry for forming such patterns is photolithography. A typical photolithography process sequence generally includes applying a uniform photoresist (resist) layer on the surface of a substrate, drying and curing the layer, patterning the layer by exposing the photoresist to intense light of a particular wavelength that is suitable for modifying the exposed layer, and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers of the track tool, and an interface that allows the tool to be operatively coupled to a lithography exposure tool.

An important factor in minimizing process variability during track lithography processing sequences is to ensure that the substrate or wafer is properly centered during the performance of processing steps. During semiconductor device processing, it is preferable to accurately center the wafer on a support platform or chuck in order to ensure the wafer will receive uniform processing across its entire process surface (e.g., uniform photoresist layers during photoresist spin processes). If a wafer is incorrectly positioned during placement within the processing chamber, it can result in uneven processing of the wafer in different regions or even cause breakage or damage to the wafer.

Therefore, there is a need for a system, a method and an apparatus that can accurately position a substrate so that it can meet desired uptime and reliability metrics while also reducing process variations and damage to the substrate.

### SUMMARY OF THE INVENTION

According to the present invention, methods and systems related to the field of substrate processing equipment are provided. More particularly, embodiments of the present invention pertain to a method and system for accurately centering a substrate within a semiconductor processing system. While embodiments of the invention may prove to be particularly useful in a track lithography tool, other embodiments of the invention can be used in other applications where it is desirable to accurately position a substrate to be processed.

In a specific embodiment of the present invention, an apparatus for substrate centering in a track lithography tool is provided. The apparatus includes a processing chamber having an opening large enough to admit a substrate. The processing chamber includes a substrate support member adapted to rotate the substrate around a substantially vertical axis. The substrate includes a mounting surface and a process surface and having a diameter. The apparatus also includes a clamped robot blade, which itself includes a substrate support surface adapted to support the substrate, two edge contact regions and a base contact region adapted to contact the edge of the substrate, and a clamping system adapted to move the edge contact positions and/or the base contact region from a first position to a second position. The substrate contacts the base contact region and the edge contact regions in the second position. The apparatus further includes a robot arm. The robot arm coupled to the clamped robot blade and configured to insert the substrate through the opening into the processing chamber.

In another embodiment of the present invention, an apparatus for substrate centering in a track lithography tool is provided. The apparatus includes a plurality of processing chambers each having openings large enough to admit a substrate. The plurality of processing chambers each includes a substrate support member adapted to rotate the substrate around a substantially vertical axis. Each substrate support member includes a mounting surface and a process surface and has a given diameter. The apparatus includes a clamped robot blade which itself further includes a substrate support surface adapted to support the substrate. two edge contact regions adapted to contact the edge of the substrate, a base contact region adapted to contact the edge of the substrate, and a clamping system adapted to move the edge contact positions and/or the base contact region from a first position to a second position. The second position is located closer to the center of the clamped robot blade. The apparatus further includes a robot arm coupled to the clamped robot blade and configured to insert and remove the substrate through the openings in the plurality of processing chambers and a substrate centering system adapted to detect an edge of the substrate. The substrate centering system includes first and a second light sources adapted to transmit a first beam of light and a second beam of light and a first and a second detector. The first and the second detectors are adapted to receive the first and the second beams of light from the first and the second light sources and transmit a signal based upon reception of the first and the second beams of light. The substrate centering system includes a processing module adapted to receive the first signal from the first and the second detectors and calculate the position of the substrate on the robot blade. The processing module is additionally adapted to transmit a second signal to a motor control module to change the location of the clamped robot blade based on the position of the substrate.

In yet another embodiment of the present invention, a method of centering a substrate in a track lithography tool is provided. The method includes providing a processing chamber having an opening large enough to admit a substrate. The processing chamber including a substrate support member adapted to rotate the substrate around a substantially vertical axis. The substrate includes a mounting surface and a process surface and having a diameter. The method further includes placing the substrate upon a clamped robot blade. The clamped robot blade includes a substrate support surface adapted to support the surface, two edge contact regions and a base contact region adapted to contact the edge of the substrate. The edge contact regions and the base contact region are adapted to contact the edge of the substrate. The method also includes securing the substrate on the clamped robot blade by moving the base contact region and/or the edge contact regions from a first position to a second position. The substrate contacts the base contact region and the edge contact regions in the second position. Additionally, the method includes moving the clamped robot blade and the substrate towards the opening of the processing chamber. The method also includes calculating the position of the substrate upon the clamped robot blade by using a substrate centering system. The substrate centering system utilizes a plurality of light beams emitted from a light source to determine the current position of the substrate. Furthermore, the method includes adjusting the position of the substrate by repositioning the clamped robot blade, moving the clamped robot blade and the substrate through the opening into the processing chamber, and unclamping the substrate from the clamped robot blade by moving the base contact region and/or the edge contact regions from a second position to a first position. The method also includes removing the substrate from the clamped robot blade; placing the substrate upon the substrate support member within the processing chamber; and removing the clamped robot blade through the opening from the semiconductor processing chamber.

Many benefits are achieved by way of the present invention over conventional techniques. For example, embodiments of the present invention allow for improved wafer handling reliability and reduced contact with the substrate, thus reducing particle generation and the risk of defects. Additional embodiments of the present invention provide reduced risk of wafer breakage or chipping, and wafer breakage can be detected at an early stage reducing the potential impact of an adverse event. Furthermore, embodiments of the present invention provide accurate placements that can help to protect expensive components used within the chamber from damage from the wafer, and can ensure proper placement even with a small placement area. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of a track lithography tool according to an embodiment of the present invention;

FIG. 2 illustrates one embodiment of a process sequence containing various process recipe steps that may be used in conjunction with the various embodiments of the cluster tool described herein;

FIG. 3 illustrates an isometric view of processing chambers retained in a processing rack that have a substrate position error detection and correction systems mounted outside each of their openings;

FIGS. 4 and 5 are simplified top views of clamped robot blades that may be used in conjunction with position correction systems for track tools according to an embodiment of the present invention;

FIG. 6 is a simplified process flow diagram showing position correction of a substrate on a robot blade according to an embodiment of the present invention; and

FIG. 7 is a simplified top down view showing the operation of a wafer position correction system according to an embodiment of the present invention.

### DETAILED DESCRIPTION OF SPECIFIC EMBODIMENTS

According to the present invention, methods and systems related to the field of substrate processing equipment are provided. More particularly, embodiments of the present invention pertain to a method and system for accurately centering a substrate within a semiconductor processing system. While embodiments of the invention may prove to be particularly useful in a track lithography tool, other embodiments of the invention can be used in other applications where it is desirable to accurately position a substrate to be processed.

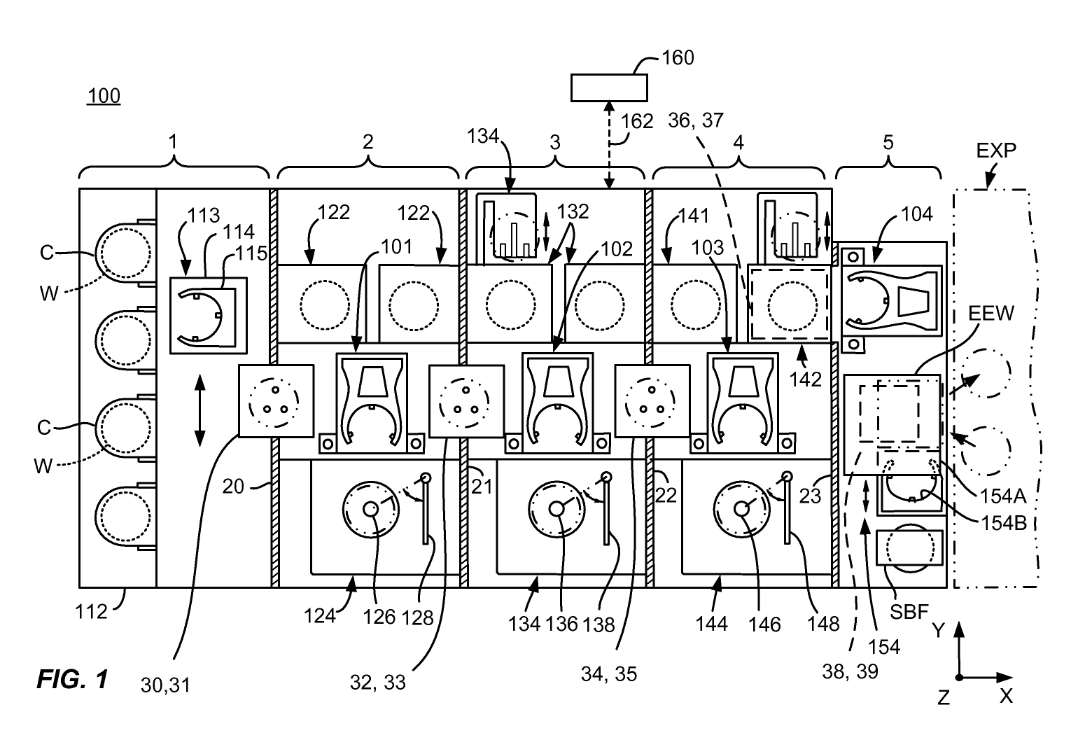

FIG. 1 is a plan view of a track lithography tool according to an embodiment of the present invention. In the embodiment illustrated in FIG. 1, the track lithography tool is coupled to an immersion scanner. An XYZ rectangular coordinate system in which an XY plane is defined as the horizontal plane and a Z axis is defined to extend in the vertical direction is additionally shown in FIG. 1 for purposes of clarifying the directional relationship therebetween.

In a particular embodiment, the track lithography tool is used to form, through use of a coating process, an anti-reflection (AR) and a photoresist film on substrates, for example, semiconductor wafers. The track lithography tool is also used to perform a development process on the substrates after they have been subjected to a pattern exposure process. Additional processes performed on the track lithography tool, which may be coupled to an immersion scanner, include PEB and the like. The substrates processed by the track lithography tool are not limited to semiconductor wafers, but may include glass substrates for a liquid crystal display device, and the like.

The track lithography tool 100 illustrated in FIG. 1 includes an factory interface block 1, a BARC (Bottom Anti-Reflection Coating) block 2, a resist coating block 3, a development processing block 4, and a scanner interface block 5. In the track lithography tool, the five processing blocks 1 to 5 are arranged in a side-by-side relation. An exposure unit (or stepper) EXP, which is an external apparatus separate from the track lithography tool is provided and coupled to the scanner interface block 5. Additionally, the track lithography tool and the exposure unit EXP are connected via LAN lines 162 to a host computer 160.

The factory interface block 1 is a processing block for transferring unprocessed substrates received from outside of the track lithography tool to the BARC block 2 and the resist coating block 3. The factory interface block 1 is also useful for transporting processed substrates received from the development processing block 4 to the outside of the track lithography tool. The factory interface block 1 includes a table 112 configured to receive a number of (in the illustrated embodiment, four) cassettes (or carriers) C, and a substrate transfer mechanism 113 for retrieving an unprocessed substrate W from each of the cassettes C and for storing a processed substrate W in each of the cassettes C. The substrate transfer mechanism 113 includes a movable base 114, which is movable in the Y direction (horizontally) along the table 112, and a robot arm 115 mounted on the movable base 114.

The robot arm 115 is configured to support a substrate W in a horizontal position during wafer transfer operations. Additionally, the robot arm 115 is capable of moving in the Z direction (vertically) in relation to the movable base 114, pivoting within a horizontal plane, and translating back and forth in the direction of the pivot radius. Thus, using the substrate transfer mechanism 113, the holding arm 115 is able to gain access to each of the cassettes C, retrieve an unprocessed substrate W out of each cassette C, and store a processed substrate W in each cassette C. The cassettes C may be one or several types including: an SMIF (standard mechanical interface) pod; an OC (open cassette), which exposes stored substrates W to the atmosphere; or a FOUP (front opening unified pod), which stores substrates W in an enclosed or sealed space.

The BARC block 2 is positioned adjacent to the factory interface block 1. Partition 20 may be used to provide an atmospheric seal between the factory interface block 1 and the BARC block 2. The partition 20 is provided with a pair of vertically arranged substrate rest parts 30 and 31 each used as a transfer position when transferring a substrate W between the factory interface block 1 and the BARC block 2.

Referring to FIG. 1 again, BARC block 2 includes a bottom coating processor 124 configured to coat the surface of a substrate W with the AR film, a pair of thermal processing towers 122 for performing one or more thermal processes that accompany the formation of the AR film, and the transport robot 101, which is used in transferring and receiving a substrate W to and from the bottom coating processor 124 and the pair of thermal processing towers 122. Each of the coating processing units includes a spin chuck 126 on which the substrate W is rotated in a substantially horizontal plane while the substrate W is held in a substantially horizontal position through suction. Each coating processing unit also includes a coating nozzle 128 used to apply a coating solution for the AR film onto the substrate W held on the spin chuck 126, a spin motor (not shown) configured to rotatably drive the spin chuck 126, a cup (not shown) surrounding the substrate W held on the spin chuck 22, and the like.

The resist coating block 3 is a processing block for forming a resist film on the substrate W after formation of the AR film in the BARC block 2. In a particular embodiment, a chemically amplified resist is used as the photoresist. The resist coating block 3 includes a resist coating processor 134 used to form the resist film on top of the AR film, a pair of thermal processing towers 132 for performing one or more thermal processes accompanying the resist coating process, and the transport robot 102, which is used to transfer and receive a substrate W to and from the resist coating processor 134 and the pair of thermal processing towers 132. Each of the coating processing units includes a spin chuck 136, a coating nozzle 138 for applying a resist coating to the substrate W, a spin motor (not shown), a cup (not shown), and the like.

The thermal processing towers 132 include a number of vertically stacked bake chambers and cool plates. In a particular embodiment, the thermal processing tower closest to the factory interface block 1 includes bake chambers and the thermal processing tower farthest from the factory interface block 1 includes cool plates. In the embodiment illustrated in FIG. 1, the bake chambers include a vertically stacked bake plate and temporary substrate holder as well as a local transport mechanism 134 configured to move vertically and horizontally to transport a substrate W between the bake plate and the temporary substrate holder and may include an actively chilled transport arm. The transport robot 102 is identical in construction to the transport robot 101 in some embodiments. The transport robot 102 is able to independently access substrate rest parts 32 and 33, the thermal processing towers 132, the coating processing units provided in the resist coating processor 134, and the substrate rest parts 34 and 35.

The development processing block 4 is positioned between the resist coating block 3 and the scanner interface block 5. A partition 22 for sealing the development processing block from the atmosphere of the resist coating block 3 is provided. The development processing block 4 includes a development processor 144 for applying a developing solution to a substrate W after exposure in the scanner EXP, a pair of thermal processing towers 141 and 142, and transport robot 103. Each of the development processing units includes a spin chuck 146, a nozzle 148 for applying developer to a substrate W, a spin motor (not shown), a cup (not shown), and the like.

The interface block 5 is used to transfer a coated substrate W to the scanner EXP and to transfer an exposed substrate to the development processing block 5. The interface block 5 in this illustrated embodiment includes a transport mechanism 154 for transferring and receiving a substrate W to and from the exposure unit EXP, a pair of edge exposure units EEW for exposing the periphery of a coated substrate, and transport robot 104. Substrate rest parts 39 and 39 are provided along with the pair of edge exposure units EEW for transferring substrates to and from the scanner and the development processing unit 4.

The transport mechanism 154 includes a movable base 154A and a holding arm 154B mounted on the movable base 154A. The holding arm 154B is capable of moving vertically, pivoting, and moving back and forth in the direction of the pivot radius relative to the movable base 154A. The send buffer SBF is provided to temporarily store a substrate W prior to the exposure process if the exposure unit EXP is unable to accept the substrate W, and includes a cabinet capable of storing a plurality of substrates W in tiers.

Controller 160 is used to control all of the components and processes performed in the cluster tool. The controller 160 is generally adapted to communicate with the scanner EXP, monitor and control aspects of the processes performed in the cluster tool, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chambers. Preferably, the program is software readable by the controller 160 and includes instructions to monitor and control the process based on defined rules and input data.

Additional description of a substrate processing apparatus in accordance with embodiments of the present invention is provided in U.S. Patent Application Publication No. 2006/0245855, entitled “Substrate Processing Apparatus,” the disclosure of which is hereby incorporated by reference in its entirety. Although embodiments of the present invention are described herein in the context of the track lithography tool illustrated in FIG. 1, other architectures for track lithography tools are included within the scope of embodiments of the present invention. For example, track lithography tools utilizing Cartesian architectures are suitable for use with embodiments as described throughout the present specification. In a particular embodiment, implementation is performed for an RF³i, available from Sokudo Co., Ltd., of Kyoto, Japan.

Photolithography Process Sequence

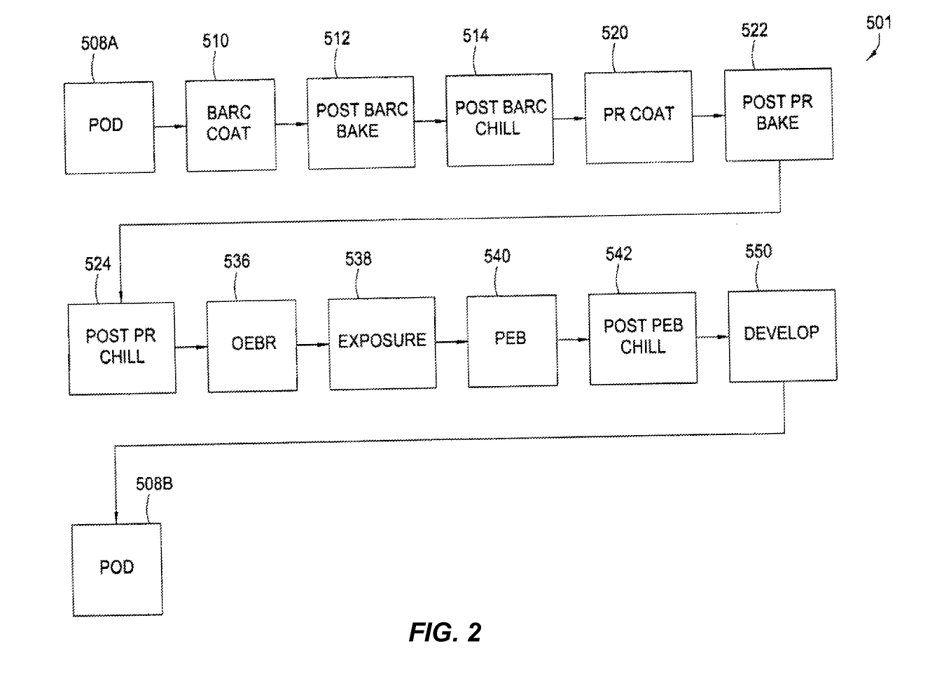

FIG. 2 illustrates one embodiment of a series of method steps 501 that may be used to deposit, expose and develop a photoresist material layer formed on a substrate surface. The lithographic process may generally contain the following: a remove substrate from pod 508A step, a BARC step 510, a post BARC bake step 512, a post BARC chill step 514, a photoresist coat step 520, a post photoresist coat bake step 522, a post photoresist chill step 524, an optical edge bead removal (OEBR) step 536, an exposure step 538, a post exposure bake (PEB) step 540, a post PEB chill step 542, a develop step 550, and a place in pod step 508B. In other embodiments, the sequence of the method steps 501 may be rearranged, altered, one or more steps may be removed, or two or more steps may be combined into a single step without varying from the basic scope of the invention.

The remove substrate from pod 508A step is generally defined as the process of having the front end robot 108 remove a substrate from a cassette 106 resting in one of the pod assemblies 105. A cassette 106, containing one or more substrates “W”, is placed on the pod assembly 105 by the user or some external device (not shown) so that the substrates can be processed in the cluster tool 100 by a user-defined substrate processing sequence controlled by software retained in the system controller 101.

The BARC coat step 510, or bottom anti-reflective coating process (hereafter BARC), is a step used to deposit an organic material over a surface of the substrate. The BARC layer is typically an organic coating that is applied onto the substrate prior to the photoresist layer to absorb light that otherwise would be reflected from the surface of the substrate back into the photoresist during the exposure step 538 performed in the stepper/scanner EXP. If these reflections are not prevented, optical standing waves will be established in the photoresist layer, which cause feature size(s) to vary from one location to another depending on the local thickness of the photoresist layer. The BARC layer may also be used to level (or planarize) the substrate surface topography, since surface topography variations are invariably present after completing multiple electronic device fabrication steps. The BARC material fills around and over the features to create a flatter surface for photoresist application and reduces local variations in photoresist thickness. The BARC coat step 510 is typically performed using a conventional spin-on photoresist dispense process in which an amount of the BARC material is deposited on the surface of the substrate while the substrate is being rotated, which causes a solvent in the BARC material to evaporate and thus causes the material properties of the deposited BARC material to change. The air flow and exhaust flow rate in the BARC processing chamber is often controlled to control the solvent vaporization process and the properties of the layer formed on the substrate surface.

The post BARC bake step 512, is a step used to assure that all of the solvent is removed from the deposited BARC layer in the BARC coat step 510, and in some cases to promote adhesion of the BARC layer to the surface of the substrate. The temperature of the post BARC bake step 512 is dependent on the type of BARC material deposited on the surface of the substrate, but will generally be less than about 250° C. The time required to complete the post BARC bake step 512 will depend on the temperature of the substrate during the post BARC bake step, but will generally be less than about 60 seconds.

The post BARC chill step 514, is a step used to assure that the time the substrate is at a temperature above ambient temperature is controlled so that every substrate sees the same time-temperature profile; thus process variability is minimized. Variations in the BARC process time-temperature profile, which is a component of a substrate's wafer history, can have an effect on the properties of the deposited film layer and thus is often controlled to minimize process variability. The post BARC chill step 514, is typically used to cool the substrate after the post BARC bake step 512 to a temperature at or near ambient temperature. The time required to complete the post BARC chill step 514 will depend on the temperature of the substrate exiting the post BARC bake step, but will generally be less than about 30 seconds.

The photoresist coat step 520 is a step used to deposit a photoresist layer over a surface of the substrate. The photoresist layer deposited during the photoresist coat step 520 is typically a light sensitive organic coating that is applied onto the substrate and is later exposed in the stepper/scanner EXP to form the patterned features on the surface of the substrate. The photoresist coat step 520 is a typically performed using conventional spin-on photoresist dispense process in which an amount of the photoresist material is deposited on the surface of the substrate while the substrate is being rotated, thus causing a solvent in the photoresist material to evaporate and the material properties of the deposited photoresist layer to change. The air flow and exhaust flow rate in the photoresist processing chamber is controlled to control the solvent vaporization process and the properties of the layer formed on the substrate surface. In some cases it may be necessary to control the partial pressure of the solvent over the substrate surface to control the vaporization of the solvent from the photoresist during the photoresist coat step by controlling the exhaust flow rate and/or by injecting a solvent near the substrate surface. Referring to FIG. 2, to complete the photoresist coat step 520 the substrate is first positioned on a spin chuck 1033 in a coater chamber 60A. A motor rotates the spin chuck 1033 and substrate while the photoresist is dispensed onto the center of the substrate. The rotation imparts an angular torque onto the photoresist, which forces the photoresist out in a radial direction, ultimately covering the substrate.

The post photoresist coat bake step 522 is a step used to assure that most, if not all, of the solvent is removed from the deposited photoresist layer in the photoresist coat step 520, and in some cases to promote adhesion of the photoresist layer to the BARC layer. The temperature of the post photoresist coat bake step 522 is dependent on the type of photoresist material deposited on the surface of the substrate, but will generally be less than about 250° C. The time required to complete the post photoresist coat bake step 522 will depend on the temperature of the substrate during the post photoresist bake step, but will generally be less than about 60 seconds.

The post photoresist chill step 524, is a step used to control the time the substrate is at a temperature above ambient temperature so that every substrate sees the same time-temperature profile and thus process variability is minimized. Variations in the time-temperature profile can have an affect on properties of the deposited film layer and thus is often controlled to minimize process variability. The temperature of the post photoresist chill step 524, is thus used to cool the substrate after the post photoresist coat bake step 522 to a temperature at or near ambient temperature. The time required to complete the post photoresist chill step 524 will depend on the temperature of the substrate exiting the post photoresist bake step, but will generally be less than about 3 seconds.

The optical edge bead removal (OEBR) step 536, is a process used to expose the deposited light sensitive photoresist layer(s), such as the layers formed during the photoresist coat step 520 and the BARC layer formed during the BARC coat step 510, to a radiation source (not shown) so that either or both layers can be removed from the edge of the substrate and the edge exclusion of the deposited layers can be more uniformly controlled. The wavelength and intensity of the radiation used to expose the surface of the substrate will depend on the type of BARC and photoresist layers deposited on the surface of the substrate. An OEBR tool can be purchased, for example, from USHIO America, Inc. Cypress, Calif.

The exposure step 538 is a lithographic projection step applied by a lithographic projection apparatus (e.g., stepper scanner EXP) to form a pattern which is used to manufacture integrated circuits (ICs). The exposure step 538 forms a circuit pattern corresponding to an individual layer of the integrated circuit (IC) device on the substrate surface, by exposing the photosensitive materials, such as, the photoresist layer formed during the photoresist coat step 520 and the BARC layer formed during the BARC coat step 510 (photoresist) of some form of electromagnetic radiation. The stepper/scanner EXP, which may be purchased from Cannon, Nikon, or ASML.

The post exposure bake (PEB) step 540 is a step used to heat a substrate immediately after the exposure step 538 in order to stimulate diffusion of the photoactive compound(s) and reduce the effects of standing waves in the photoresist layer. For a chemically amplified photoresist, the PEB step also causes a catalyzed chemical reaction that changes the solubility of the photoresist. The control of the temperature during the PEB is critical to critical dimension (CD) control. The temperature of the PEB step 540 is dependent on the type of photoresist material deposited on the surface of the substrate, but will generally be less than about 250° C. The time required to complete the PEB step 540 will depend on the temperature of the substrate during the PEB step, but will generally be less than about 60 seconds.

The post exposure bake (PEB) chill step 542 is a step used to assure that the time the substrate is at a temperature above ambient temperature is controlled, so that every substrate sees the same time-temperature profile and thus process variability is minimized. Variation in the PEB process time-temperature profile can have an effect on properties of the deposited film layer and thus is often controlled to minimize process variability. The temperature of the post PEB chill step 542 is thus used to cool the substrate after the PEB step 540 to a temperature at or near ambient temperature. The time required to complete the post PEB chill step 542 will depend on the temperature of the substrate exiting the PEB step, but will generally be less than about 30 seconds.

The develop step 550 is a process in which a solvent is used to cause a chemical or physical change to the exposed or unexposed photoresist and BARC layers to expose the pattern formed during the exposure step 538. The develop process may be a spray or immersion or puddle type process that is used to dispense the developer solvent. In one embodiment of the develop step 550, after the solvent has been dispensed on the surface of the substrate a rinse step may be performed to rinse the solvent material from the surface of the substrate. The rinse solution dispensed on the surface of the substrate may contain deionized water and/or a surfactant.

The insertion of the substrate in pod step 508B is generally defined as the process of having the front end robot 108 return the substrate to a cassette 106 resting in one of the pod assemblies 105.

While an exemplary embodiment of a lithograph photolithography processing sequence has been described in regards to FIG. 2, other embodiments are also possible to one of skill in the art. For example, a hexamethydisilazane (HMDS) process may be used in place of the BARC process, a top anti-reflective coating layer (TARC) may be formed, or a SAFIER™ (shrink assist for enhanced resolution) process may be used. Of course, other alternatives or possibilities are also available to one of skill in the art.

Substrate Center Finding Device

In an effort to be more competitive in the market place and thus reduce CoO, electronic device manufacturers often spend a large amount of time trying to improve the system uptime and system reliability to reduce substrate scrap and increase the total system throughput (i.e., wafers starts per week). One factor that can affect the system uptime and reliability is the misplacement of substrates in the various processing chambers which can cause substrate damage (e.g., chipping, substrate breakage, etc.). Damage to the substrates will cause the user to shut down the current process, scrap all of the partially processed substrates, clean the affected chamber(s) and then restart the process sequence, all leading to significant system downtime and cost. Typically, to prevent substrate to substrate process variation and damage to the substrate caused by misalignment of the substrate in one of the processing chambers, or other chambers, the robot is repeatedly calibrated to pick up and drop off a substrate from a transfer position. The transfer position may be, for example, the center point between the process chamber lift pins or the center point of the chuck.

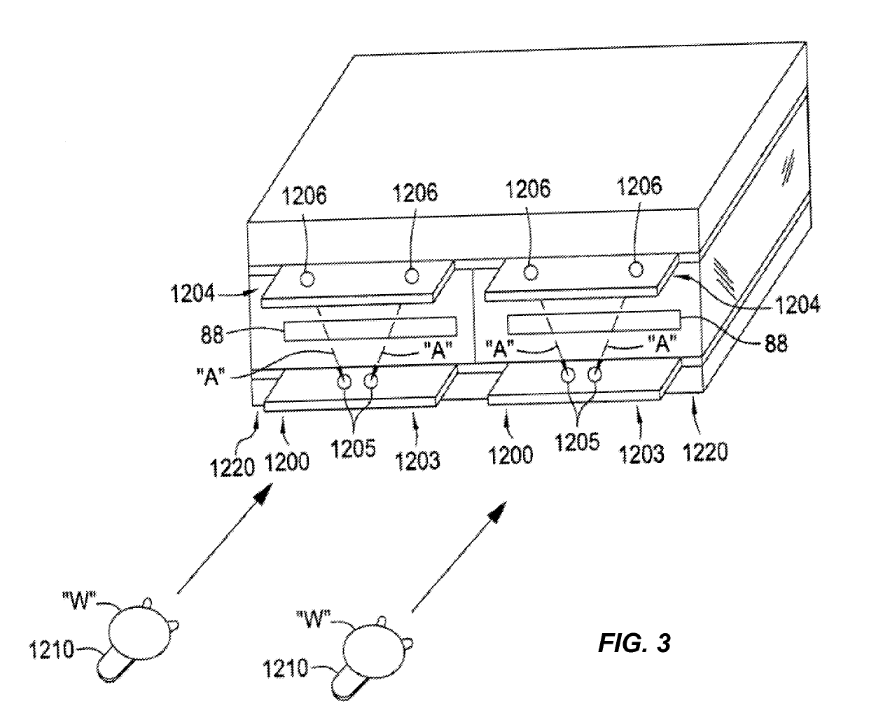

To solve these problems, in one embodiment of the cluster tool 100, a substrate position error detection and correction system 1200 (hereafter SPEDAC 1200), shown in FIG. 3, is used. FIG. 3 illustrates an isometric view of two adjacent process chambers 1220 (e.g., a bake chamber, chill chamber, coater/developer chamber, or the like) retained in a processing rack that have two separate substrate position error detection and correction systems 1200 mounted outside each of their openings 88. FIG. 3 illustrates one embodiment of the SPEDAC system 1200 in which the transmitters 1206 are mounted to a top support 1204 and the detectors 1205 are mounted in a bottom support 1203 which are all connected to the process chamber 1220.

The SPEDAC system 1200 determines the presence of a substrate on a substrate transport robot blade as it enters or exits the opening 88 found in the various processing chambers and corrects for any error by repositioning the robot blade 1210 in subsequent transferring steps. The SPEDAC system 1200 utilizes a pair of beams (item “A”) sent from two pairs of transmitters 1206 to detectors 1205 to detect the position of the substrate as it passes through the beams and adjusts the robot position to compensate for any error in the substrate's position. When a substrate position error is detected, the system determines the extent of the misalignment and corrects such misalignment, if correctable, by the movement of the robot blade position or alerts an operator for operator intervention. Further description of an exemplary method of detecting and compensating for substrate misplacement on the blade of the robot is further described in U.S. Pat. No. 5,563,798, entitled “Wafer Positioning System,” issued Oct. 8, 1996, U.S. Pat. No. 5,483,138, entitled “System and Method for Automated Positioning of a Substrate in a Processing Chamber,” issued Jan. 9, 1996, and U.S. Pat. No. 5,980,194, issued Nov. 9, 1999, to Freerks, et al., which are incorporated by reference in their entirety to the extent not inconsistent with the present disclosure. An example of an exemplary method to control robot position and thus substrate position is further described in U.S. Pat. No. 6,556,887, issued Apr. 29, 2003 to Freeman, et al., which is incorporated by reference in their entirety to the extent not inconsistent with the present disclosure.

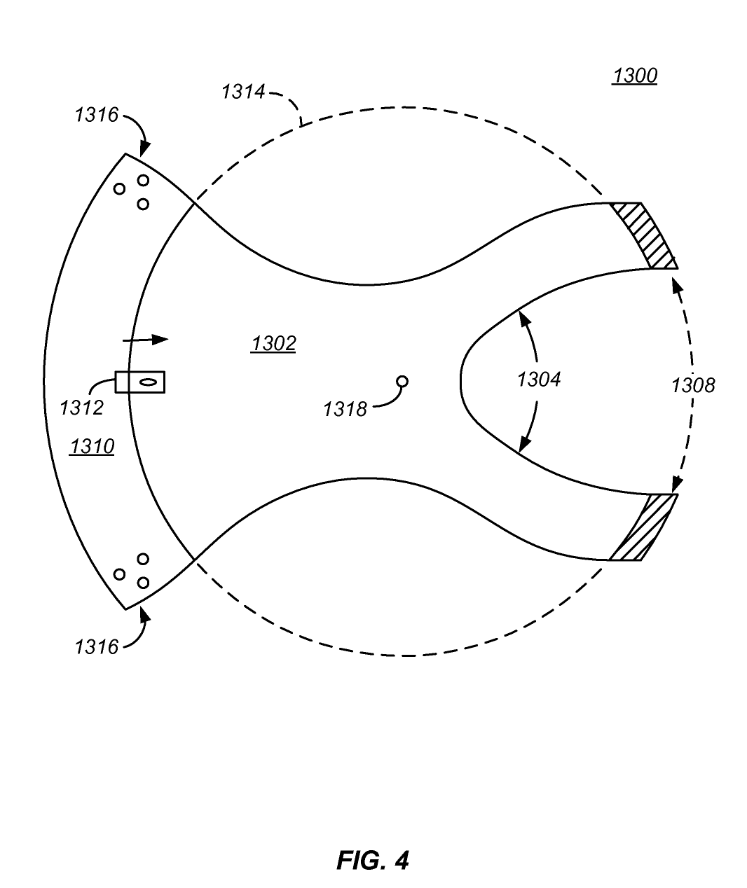

FIG. 4 is a simplified top view of a clamped robot blade that may be used in conjunction with a position correction system for a track tool according to an embodiment of the present invention. Clamped robot blade 1300 may support substrates of different sizes and shapes depending upon the processes and applications being used. For example, the clamped robot blade may support semiconductor substrates with a diameter of 150 mm, 200 mm, 300 mm, 400 mm, and the like. The material used in the composition of the clamped robot blade may also vary depending upon the specific processes and applications being used. For example, ceramic, metal, or other high strength materials may be used. The majority of the weight of substrates resting upon clamped robot blade 1300 is supported by body region 1302 of clamped robot blade 1300. For example, body region 1302 may have a curved or straight profile as needed. Centering hole 1318 may be present to aid in robot calibration and the positioning of clamped robot blade 1300 within the processing chambers. For example, a cylindrical rod (not shown) may be placed vertically through centering hole 1318 and an indentation in the top surface of the substrate support (not shown) within the process chamber when clamped robot blade 1300 is correctly centered to the substrate support. If the cylindrical rod cannot be placed through both centering hole 1318 and the indentation in the top surface of the substrate support, additional calibration may be required.

Clamped robot blade 1300 may be coupled to a robot at base region 1310. For example, screws 1316 or other methods of attachment may be used to couple clamped robot blade 1300 with a robot. Base region 1310 is normally at an elevated height as compared to body region 1310 to prevent the substrate from slipping during movement of the robot. The side of base region 1310 facing the edge of the substrate may have a polished, treated, or finished surface to prevent damage or chipping to the edge of the substrate with body region 1310.

Body region 1302 splits into finger regions 1304 away from base region 1310. At the end of finger regions are edge contact regions 1308 adapted to contact the edge of the wafer at at least two areas. Edge contact regions 1308 may also be at an elevated height to constrain movement of the substrate. Additionally, sides of edge contact regions 1308 may have a polished, treated, or finished surface to prevent damage or chipping to the edge of the substrate during contact with body region 1310.

Edge contact regions and base region 1310 form a pocket region 1314 suitable for the placement of a substrate upon clamped robot blade 1300. Pocket region 1314 may be slightly larger than the size of the substrate to accommodate for a margin of error in the placement of the substrate upon clamped robot blade 1300. For example, if clamped robot blade 1300 is designed for use with 300 mm substrates, pocket region 1314 may have a diameter of 302 mm, 303 mm, or the like.

A clamping system is integrated within clamped robot blade 1300 to adequately secure the substrate during movement to and from process chambers in the track tool. The clamping system may use mechanical, electrical, or other means to actuate movement of one or more components integrated within or coupled to clamped robot blade 1300. In a specific embodiment of the present invention, base region 1310 incorporates a base contact region 1312 which may shift position to contact the edge of the substrate. For example, base contact region may be formed from a material suitable for contact with the edge of the wafer, such as a soft, rubberlike, or shatter-resistant material. Of course, other materials may also be used by those of skill in the art. In a first position, base contact region 1312 is not extended to allow for the substrate to be positioned within pocket region 1314 onto the clamped robot blade 1300. Once the substrate has been placed upon clamped robot blade 1314, base contact region 1312 shifts to a second position towards the center of the robot blade 1300 to contact the edge of the substrate. In the second position, the wafer is contacted at three areas at the edge contact regions and the base contact region to ensure that the substrate is stable for transport and loading into and out from the processing chambers. When the substrate is to be unloaded onto a substrate support from clamped robot blade 1300, base contact region 1312 may move to the first position, thus releasing the substrate and allowing for removal of the substrate from the clamped robot blade for processing.

One advantage of utilizing a clamped robot blade within a track tool is that it can provide for more accurate placement of the substrate within the processing chamber. By doing so, variation in processes performed on the substrate can be greatly reduced. This is particularly true in regards to lithography processing systems which may have little tolerance for variation in process results. Additionally, more accurate placement also reduces the risk of physical damage to the substrate and/or equipment as a result of user/system errors.

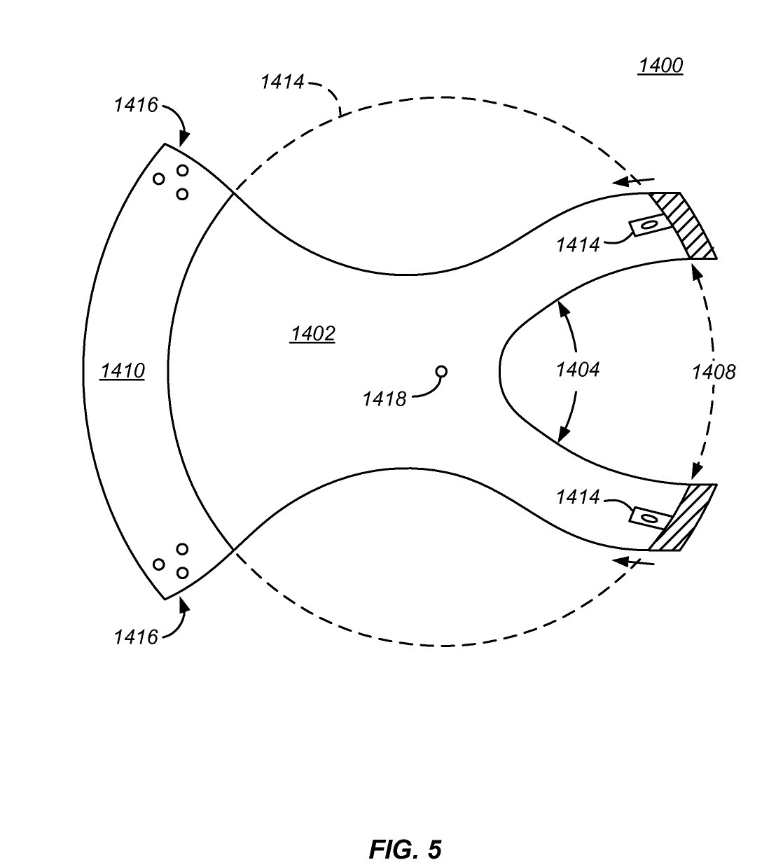

FIG. 5 is another simplified top view of a clamped robot blade that may be used in conjunction with a position correction system for a track tool according to an embodiment of the present invention. In one embodiment, the clamped robot blade 1400 generally contains all of the components contained in the clamped robot blade 1300 and thus some components of the clamped robot blade 1400 that are the same or similar to those described with reference to the clamped robot blade 1300, have the same numbers. Accordingly, like numbers have been used where appropriate. In FIG. 5, edge contact regions 1408 are moveable towards base region 1410 to contact the edge of a substrate. For example, in a first position edge contact regions 1408 are in an open position to allow for placement of the substrate upon clamped robot blade 1400. When the substrate has been placed upon clamped robot blade 1400, edge contact regions 1408 move inward to contact the edge of the substrate, thus securing the substrate in at least three areas at the base contact region and edge contact regions.

While two configurations have been described for the clamped robot blade, other configurations may be used for the clamping system known to those of skill in the art. For example, other methods of clamping the wafer or other blade shapes, sizes or materials may be used. In another example, edge contact regions and base contact regions may both be moveable to contact a substrate in a second position.

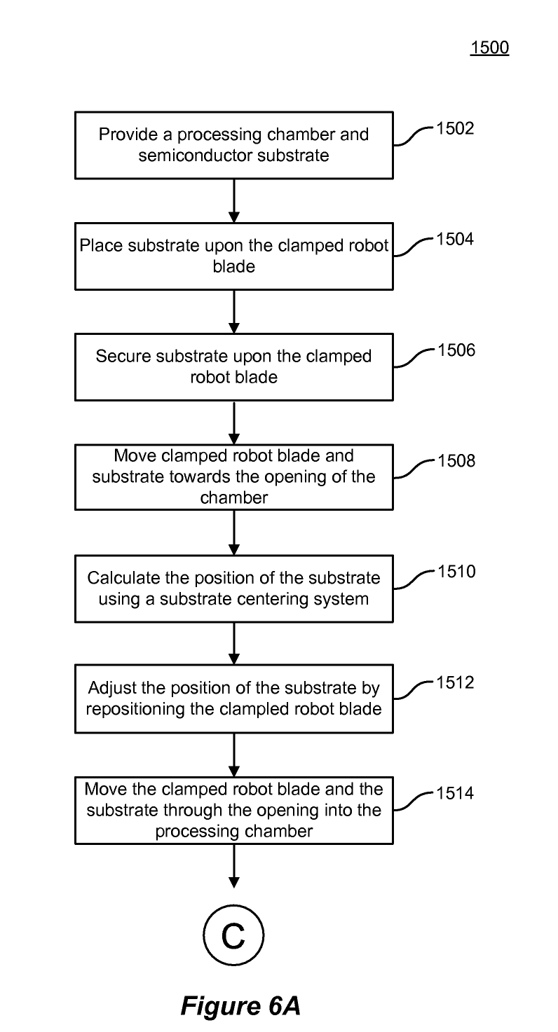

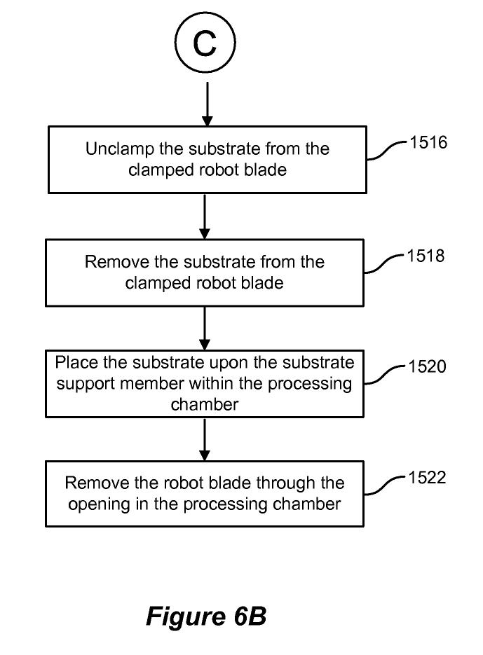

FIG. 6 is a simplified process flow diagram showing position correction of a substrate on a robot blade according to an embodiment of the present invention. The sequence of processes 1500 may generally contain the following: a process 1502 for providing a processing chamber and semiconductor substrate, a process 1504 for placing the substrate upon the clamped robot blade, a process 1504 for securing the substrate upon the clamped robot blade, a process 1506 for securing the substrate upon the clamped robot blade, a process 1508 for moving the clamped robot blade and the substrate towards the opening of the chamber, a process 1510 for calculating the position of the substrate using a substrate centering system, a process 1512 for adjusting the position of the substrate by repositioning the clamped robot blade, a process 1514 for moving the clamped robot blade and the substrate through the opening into the processing chamber, a process 1516 for unclamping the substrate from the clamped robot blade, a process 1518 for removing the substrate from the clamped robot blade, a process 1520 for placing the substrate upon a substrate support member within the processing chamber, and a process 1522 for removing the robot blade through the opening in the processing chamber. In other embodiments, the sequence of processes 1500 may be rearranged, altered, one or more processes may be removed, or two or more processes may be combined into a single process without varying from the basic scope of the invention.

In process 1502, a processing chamber and semiconductor substrate are provided. For example, the processing chamber may be a coat, develop, bake, chill, stepper/scanner or other type of chamber used within a track lithography tool. In a specific embodiment of the invention, a plurality of processing chambers such as a vertical stack of processing chambers such as coat or dispense chambers may also be employed. In process 1504, the substrate is placed upon the clamped robot blade. Preferably, the clamped robot blade may be in an unclamped position to receive the substrate. For example, the clamped robot blade may have a base contact region and two or more edge contact regions adapted to contact the edge of the substrate without causing chipping or damage to the substrate, as shown in FIGS. 4 and 5 and 9B The edge contact regions and or the base contact region may be located in a first position to allow the substrate to placed on the clamped robot blade.

In process 1506, the substrate is secured upon the clamped robot blade for transport to a processing chamber. A number of different methods as known to those of skill in the art may be employed to secure the wafer to the clamped robot blade. For example, the base contact regions and/or edge contact regions may be movably configured to switch between a first position where the substrate is contacted on less than three areas and a second position where the substrate is contacted on at least three areas. By contacting the wafer at three or more areas, an optimal amount of stability and control may be achieved for substrate processing.

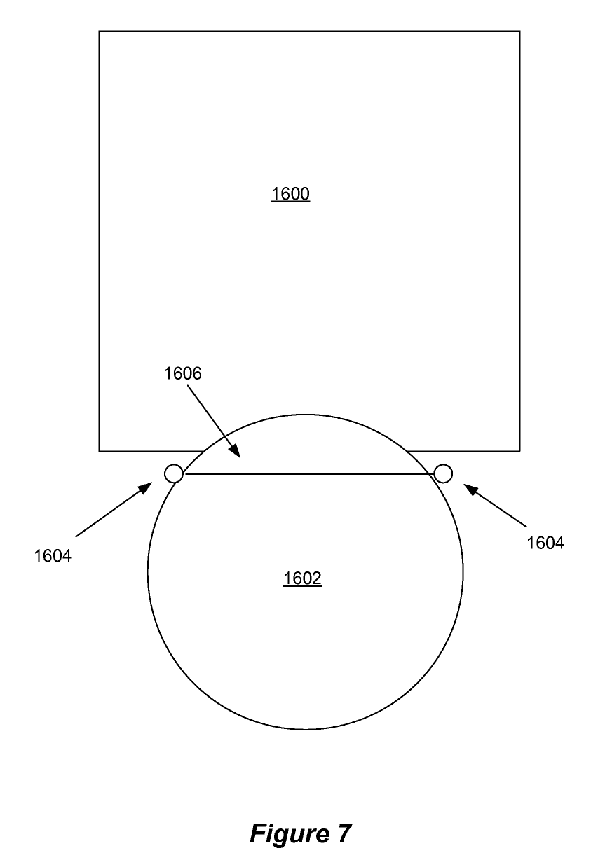

In process 1508, the clamped robot blade and the substrate are moved towards an opening of the processing chamber. In process 1510, the position of the substrate upon the clamped robot blade is calculated using a substrate centering system. This process may be better understood in reference to FIG. 7, which is a simplified top down view showing the operation of a wafer position correction system. Substrate 1602 is secured upon a clamped robot blade (not shown) and is entering processing chamber 1600. Processing chamber 1600 utilizes a substrate centering system, which includes first and second light sources 1604 adapted to transmit beams of light to detector units (not shown). The detector units may be located directly below first and second light sources 1604 or at a given angle. The detector units are adapted to receive the beams of light from the light sources and transmit a signal based upon reception of the beams of light. The light sources may be LED or laser emitters adapted to transmit light to a corresponding set of receivers. The light sources may be placed a fixed width apart to be used for determination of a substrate chord as the substrate begins to pass into the chamber. Using that information, a processing module coupled to the detector units can calculate the position of the substrate on the robot blade and determine the count of the leading and trailing substrate edges as they enter the processing chamber. The processing module then transmits a second signal to a motor control module to calculate the offsets necessary to recenter the substrate. The robot can then move the required distance necessary to accurately center the substrate. If multiple chambers such as a vertical stack of chambers are employed, a single substrate centering system can be used to center the substrate for all chambers within the stack, thus reducing the amount of time required to properly center the wafer during each processing step.

The utilization of a wafer centering process can allow for improved wafer handling reliability. The noncontact method employed reduces contact with the substrate, thus reducing particle generation and the risk of defects. In addition, precise centering reduces the risk of wafer breakage or chipping, and wafer breakage can be detected at an early stage reducing the potential impact of an adverse event. In addition, wafer centering can also provide specific benefits to lithography or other applications. For example, accurate placements can help to protect expensive components used within the chamber from damage from the wafer, and can ensure proper placement even with a small placement area. In a specific embodiment of the invention, the center finding system may be selectable upon chamber entry or exit.

Once the wafer has been properly centered, the clamped robot blade and substrate can be moved through the opening in the processing chamber in process 1514. The substrate is unclamped from the robot blade in process 1516, allowing the substrate to be removed from the substrate in process 1518. The substrate is placed upon a substrate support member in process 1520, and the clamped robot blade can be removed through the opening in the process chamber in process 1522. The wafer has now been accurately placed within the chamber and processing can begin.

While the above is a complete description of the embodiments of the present invention, it is possible to use various alternatives, modifications and equivalents. For example, in an alternative embodiment of the invention, an unclamped robot blade could also be used in conjunction with the wafer centering system. Alternatively, embodiments of the invention could be used within different semiconductor processing tools other than lithography track tools. Therefore, the scope of the present invention should be determined not with reference to the above description but should, instead, be determined with reference to the appended claim, along with their full scope of equivalents.

What is claimed is:

1. An apparatus for centering a substrate in a track lithography tool, the apparatus comprising:
a processing chamber having an opening large enough to admit the substrate, the processing chamber including a substrate support member adapted to rotate the substrate around a substantially vertical axis, wherein the substrate is characterized by a diameter and comprises a mounting surface, a process surface, and an edge;
a clamped robot blade comprising:
a substrate support surface adapted to support the mounting surface of the substrate;
two edge contact regions and a base contact region, each of the two edge contact regions and the base contact region being adapted to contact the edge of the substrate in a clamped position; and
a clamping system adapted to move at least one of the two edge contact regions or the base contact region from an unclamped position to a clamped position, thereby making contact between the edge of the substrate and the two edge contact regions and the base contact region in the clamped position; and
a robot arm, the robot arm coupled to the clamped robot blade and configured to insert the substrate through the opening into the processing chamber.

2. The apparatus of claim 1 wherein the at least one of the two edge contact regions or the base contact region are free from contact with the edge of the substrate in the unclamped position.

3. The apparatus of claim 1 wherein the two edge contact regions and the base contact region form three points on a circle having a diameter slightly larger than the diameter of the substrate.

4. The apparatus of claim 1 wherein the diameter of the substrate is greater than or equal to 300 mm.

5. The apparatus of claim 1 wherein a top surface of the edge contact regions is higher than the substrate support surface.

6. The apparatus of claim 1 wherein the clamped robot blade further comprises a base region, a top surface of the base region being higher than the substrate support surface.

7. The apparatus of claim 1 further comprising a central fluid dispense bank comprising a plurality of dispense nozzles coupled to a plurality of fluid sources, the central fluid bank adapted to dispense fluid onto the process surface of the substrate within the processing chamber.

8. The apparatus of claim 1 wherein the clamped robot blade comprises a ceramic material.

9. The apparatus of claim 1 wherein the clamped robot blade comprises a metallic material.

10. The apparatus of claim 1 further comprising:
a substrate centering system adapted to detect an edge of the substrate, the substrate centering system including:
first and a second light sources adapted to transmit a first beam of light and a second beam of light;
a first and a second detector, the first and the second detectors adapted to receive the first and the second beams of light from the first and the second light sources and transmit a signal based upon reception of the first and the second beams of light; and
a processing module, the processing module adapted to receive the first signal from the first and the second detectors and calculate the position of the substrate on the clamped robot blade, the processing module additionally adapted to transmit a second signal to a motor control module to change the position of the clamped robot blade.

11. The apparatus of claim 10 wherein the first and the second light sources are separated a fixed width apart.

12. The apparatus of claim 10 wherein the position of the substrate on the robot blade is calculated by determining a chord of the wafer as it enters the processing chamber.

13. The apparatus of claim 10 wherein the substrate centering system is mounted on the exterior of the processing chamber.

14. An apparatus for centering a substrate in a track lithography tool, the apparatus comprising:
a plurality of processing chambers each having openings large enough to admit the substrate, the plurality of processing chambers each including a substrate support member adapted to rotate the substrate around a substantially vertical axis, wherein the substrate is characterized by a diameter and comprises a mounting surface, a process surface, and an edge;
a clamped robot blade comprising:
a substrate support surface adapted to support the substrate;
two edge contact regions adapted to contact the edge of the substrate;
a base contact region adapted to contact the edge of the substrate; and
a clamping system adapted to move at least one of the two edge contact regions or the base contact region from an unclamped position to a clamped position, the second position located closer to the center of the clamped robot blade.
a robot arm coupled to the clamped robot blade and configured to insert and remove the substrate through the openings in the plurality of processing chambers;
a motor control module coupled to the robot arm and adapted to control a location of the clamped robot blade; and
a substrate centering system adapted to detect the edge of the substrate, the substrate centering system including:
a first light source adapted to transmit a first beam of light;
a second light adapted to transmit a second beam of light;
a first detector adapted to receive the first beam of light and transmit a first signal based on reception of the first beam of light;
a second detector adapted to receive the second beam of light and transmit a second signal based upon reception of the second beam of light; and
a processing module adapted to receive the first signal and the second signal and calculate a position of the edge of the substrate in relation to the clamped robot blade, the processing module additionally adapted to transmit a third signal to the motor control module.

15. The apparatus of claim 14 wherein the diameter of the substrate is greater than or equal to 300 mm.

16. The apparatus of claim 14 wherein the clamped robot blade contacts at least three areas on the edge of the wafer when the clamping mechanism is in the clamped position.

17. The apparatus of claim 14 wherein the clamped robot blade contacts less than three areas on the edge of the wafer when the clamping mechanism is in a first position.

18. A method of centering a substrate in a track lithography tool having a plurality of processing chambers, the substrate having an edge and being characterized by a diameter, the method including:
placing the substrate upon a clamped robot blade, wherein the clamped robot blade includes a substrate support surface, two edge contact regions, and a base contact region;
securing the substrate on the clamped robot blade by moving at least one of the two edge contact regions or the base contact region an unclamped position to a clamped position, wherein the two edge contact regions and the base contact region make contact with the edge of the substrate in the clamped position;
moving the clamped robot blade and the substrate towards an opening in a processing chamber;
calculating a position of the substrate upon the clamped robot blade by using a substrate centering system, the substrate centering system utilizing a plurality of light beams emitted from a light source to determine the current position of the substrate;
adjusting the position of the substrate by repositioning the clamped robot blade;
moving the clamped robot blade and the substrate through a opening into one of the plurality of processing chambers;
unclamping the substrate from the clamped robot blade by moving at least one of the two edge contact regions of the base contact region to the unclamped position;
removing the substrate from the clamped robot blade;
placing the substrate upon a substrate support member within the one of the plurality of processing chambers; and
removing the clamped robot blade through the opening into the one of the plurality of semiconductor processing chambers.

19. The method of claim 18 wherein the clamped robot blade comprises at least one of a ceramic or metallic material.

20. The method of claim 18 wherein the chamber comprises at least one of a bake chamber, a coat chamber, or a develop chamber.
